(19) United States
(12) Patent Application Publication
(10) Pub. No.: US 2014/0057206 A1
(43) Pub. Date: Feb. 27, 2014

(54) DRAWING APPARATUS AND METHOD OF MANUFACTURING ARTICLE

(71) Applicant: CANON KABUSHIKI KAISHA, Tokyo (JP)

(72) Inventor: Kazuya KIKUCHI, Utsunomiya-shi (JP)

(73) Assignee: CANON KABUSHIKI KAISHA, Tokyo (JP)

(21) Appl. No.: 13/949,408

(22) Filed: Jul. 24, 2013

(30) Foreign Application Priority Data
Aug. 22, 2012 (JP) 2012-183594

(51) Int. Cl. H01J 37/317

(52) U.S. Cl. CPC H01J 37/3174
USPC 430/296; 250/396 R; 250/397

(57) ABSTRACT

The present invention provides a drawing apparatus for performing drawing on a substrate with a plurality of charged particle beams, comprising a blanker array including a plurality of groups each including one light-emitting element and at least one blanker, and a plurality of transmission lines configured to transmit control signals to the plurality of groups, respectively, wherein each light-emitting element emits light when a signal is transmitted via a transmission line connected to a group including the light-emitting element out of the plurality of transmission lines.

### BACKGROUND OF THE INVENTION

1. Field of the Invention

The present invention relates to a drawing apparatus and a method of manufacturing an article.

2. Description of the Related Art

With miniaturization and large-scale integration of the circuit pattern of a semiconductor integrated circuit, a drawing apparatus which draws a pattern on a substrate with a plurality of charged particle beams (electron beams) is attracting a great deal of attention. In recent years, in the drawing apparatus, a demand for improving the throughput has arisen, so the number of charged particle beams is dramatically increasing to meet this demand. In such a drawing apparatus, a large number of optical signals for controlling blanking deflectors which blank a plurality of charged particle beams are transmitted to the blanking deflectors via a large number of optical fibers.

However, when a large number of optical fibers (transmission lines) are used, if an optical fiber has a problem associated with the connection state such as disconnection or improper connection between a blanking deflector and a blanking controller which controls it, it may become difficult to find a portion having the problem. To solve this problem, Japanese Patent No. 4246374 proposes a drawing apparatus including a detector which detects the irradiated position of a charged particle beam having passed through a blanking deflector. In the drawing apparatus described in Japanese Patent No. 4246374, the connection state of an optical fiber can be confirmed by detecting, using a detector, whether a charged particle beam is normally deflected by controlling the blanking deflector.

In the drawing apparatus described in Japanese Patent No. 4246374, the connection state of an optical fiber, such as disconnection or improper connection, is confirmed by detecting, using a detector, whether a charged particle beam is normally deflected. In this case, the connection state of an optical fiber is confirmed using a charged particle beam, so it is necessary to evacuate a space through which the charged particle beam passes, thus taking a long time to confirm the connection state of the optical fiber.

### SUMMARY OF THE INVENTION

The present invention provides a drawing apparatus advantageous in confirming the connection state of a transmission line.

According to one aspect of the present invention, there is provided a drawing apparatus for performing drawing on a substrate with a plurality of charged particle beams, comprising: a blanker array including a plurality of groups each including one light-emitting element and at least one blanker; and a plurality of transmission lines configured to transmit control signals to the plurality of groups, respectively, wherein each light-emitting element emits light when a signal is transmitted via a transmission line connected to a group including the light-emitting element out of the plurality of transmission lines.

Further features of the present invention will become apparent from the following description of exemplary embodiments with reference to the attached drawings.

### BRIEF DESCRIPTION OF THE DRAWINGS

FIG. 1 is a schematic view showing a drawing apparatus in the first embodiment;

FIG. 2 is a view illustrating an example of the arrangement of a plurality of charged particle beams;

FIG. 3 is a view showing the configuration of a blanker array;

FIG. 4 is a view showing the arrangement of blankers and light-emitting elements in the blanker array;

FIG. 5 is a block diagram showing transmission of signals from a blanking control circuit to a blanking deflector;

FIG. 6 is a view showing the arrangement of blankers and light-emitting elements in the blanker array;

FIG. 7 is a block diagram showing transmission of signals from a blanking control circuit to a blanking deflector;

FIG. 8 is a flowchart showing a method of confirming the connection state of an optical fiber;

FIG. 9 is a block diagram showing transmission of signals from a blanking control circuit to a blanking deflector;

FIG. 10 is a block diagram showing transmission of signals from a blanking control circuit to a blanking deflector;

FIG. 11 is a schematic view showing a drawing unit in a drawing apparatus of the third embodiment;

FIG. 12A is a view showing a blanker array in a drawing apparatus of the fourth embodiment; and

FIG. 12B is a view showing a light detector on a substrate stage in the drawing apparatus of the fourth embodiment.

### DESCRIPTION OF THE EMBODIMENTS

Exemplary embodiments of the present invention will be described below with reference to the accompanying drawings. Note that the same reference numerals denote the same members throughout the drawings, and a repetitive description thereof will not be given. Also, in each drawing, directions orthogonal to each other on a substrate surface are the X- and Y-directions, and a direction perpendicular to the substrate surface is the Z-direction.

### First Embodiment

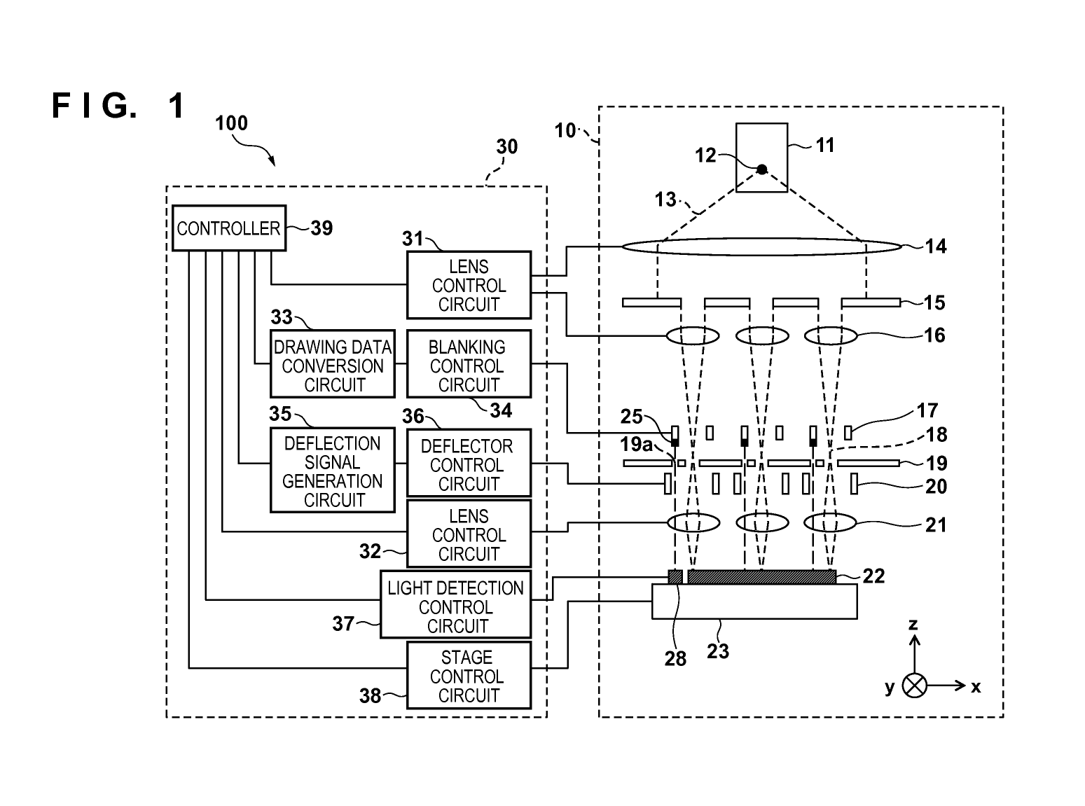

A drawing apparatus 100 in the first embodiment of the present invention will be described with reference to FIG. 1. The drawing apparatus 100 in the first embodiment includes a drawing unit 10 which irradiates a substrate with a charged particle beam to draw a pattern on the substrate, and a control unit 30 which controls each unit of the drawing unit 10. The drawing unit 10 includes, for example, a charged particle gun 11, collimator lens 14, aperture array 15, first electrostatic lenses 16, blanking deflector 17, stopper 19, deflector 20, second electrostatic lenses 21, and substrate stage 23.

A charged particle beam 13 emitted by the charged particle gun 11 forms a crossover image 12, is converted into a collimated beam by the action of the collimator lens 14, and enters the aperture array 15. The aperture array 15 has a plurality of apertures arrayed in a matrix, and splits a charged particle beam incident as a collimated beam into a plurality of charged particle beams. The charged particle beams split by the aperture array 15 enter the first electrostatic lenses 16. The charged particle beams having passed through the first electrostatic lenses 16 form intermediate images 18 of the crossover image 12, and the blanking deflector 17 including a plurality of blankers is set on the plane on which the intermediate images 18 are formed. The blanking deflector 17 individually deflects the plurality of charged particle beams, and the charged particle beams deflected by the blanking deflector 17 are blocked by the stopper 19 set in the succeeding stage of the blanking deflector 17 and do not reach the surface of a substrate 22. That is, the blanking deflector 17 switches between ON and OFF of the irradiation of the substrate 22 with the charged particle beams. The charged particle beams having passed through the stopper 19 form images of the crossover image 12 on the substrate 22, held on the movable substrate stage 23, through the deflector 20 and second electrostatic lenses 21 for scanning the charged particle beams on the substrate 22. Note that the deflector 20 can deflect the charged particle beams in a direction perpendicular to the scanning direction of the substrate stage 23, but the deflection direction of the charged particle beams is not limited to a direction perpendicular to the scanning direction of the substrate stage 23, and may be another direction.

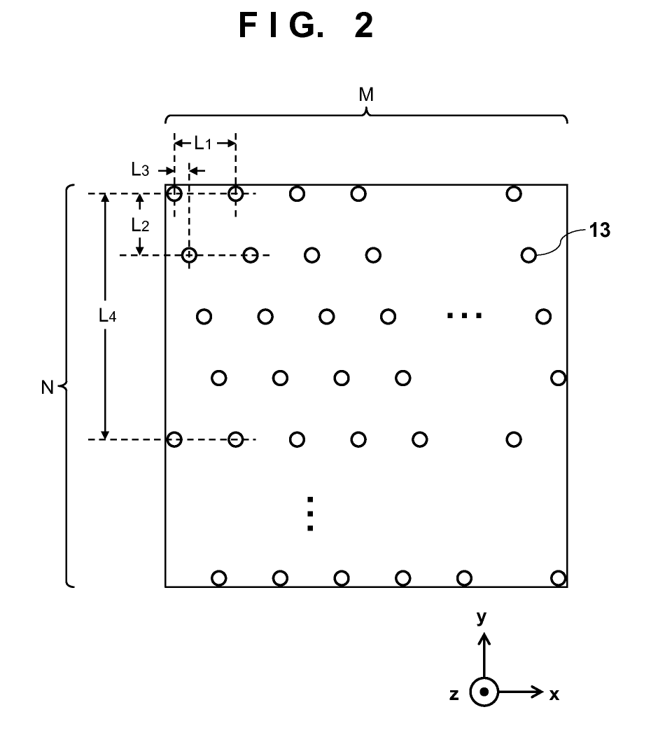

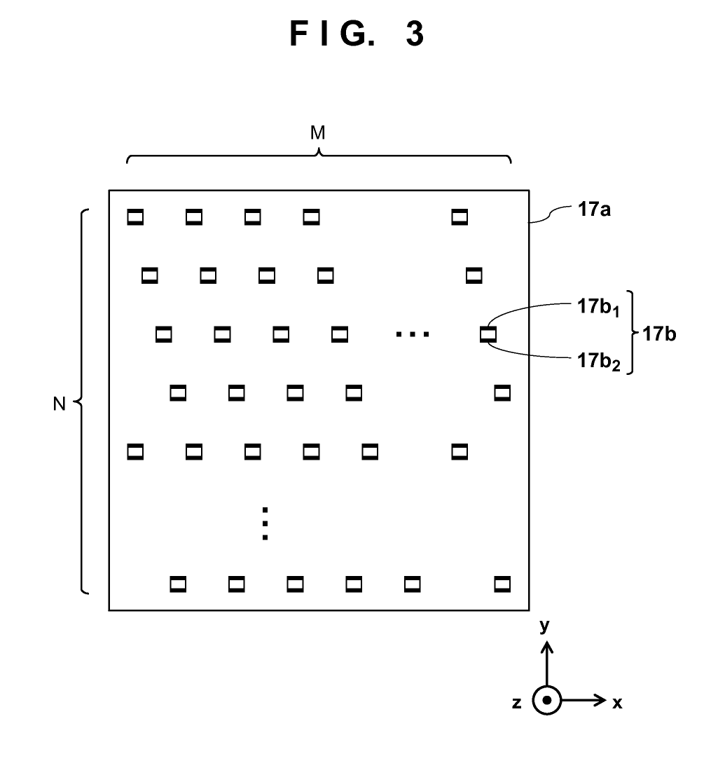

The blanking deflector 17 will be described herein, together with the arrangement of a plurality of charged particle beams. FIG. 2 is a view illustrating an example of the arrangement of a plurality of charged particle beams 13, incident on the blanking deflector 17, as viewed from the −Z-direction (the traveling direction of the charged particle beams). As the plurality of charged particle beams 13, M charged particle beams aligned at an interval L₁ in the X-direction are aligned on N rows at an interval L₂ in the −Y-direction, as shown in, for example, FIG. 2. The nth row in the −Y-direction is set to shift from the previous row ((n−1)th row) at a distance L₃ in the X-direction, and have one period corresponding to several rows in the −Y-direction. Referring to FIG. 2, four rows in the −Y-direction correspond to one period (Interval L₁=4×Distance L₃), and the arrangement of charged particle beams in the X-direction on the (n+4)th row is the same as that on the nth row (Distance L₄=4×Interval L₂). In drawing on the substrate 22, the plurality of charged particle beams 13 periodically arranged in this way are deflected in the range of the distance L₃ in the X-direction by the deflector 20 in synchronism with the position of the substrate stage 23 (substrate 22) while the substrate stage 23 continuously moves in the Y-direction. That is, each charged particle beam 13 is used to perform drawing on the substrate 22 in the range of Distance L₃×Distance L₄. The moment the moving distance of the substrate stage 23 reaches the distance L₄, drawing of one shot ends. Also, the blanking deflector 17 performs blanking control of each charged particle beam 13 in synchronism with the position of the substrate stage 23 (substrate 22). FIG. 3 is a view showing the configuration of a blanker array 17a included in the blanking deflector 17. In the blanker array 17a, a blanker 17b is arranged at a position corresponding to each charged particle beam 13 arranged as shown in FIG. 2. The blanker 17b is formed by two electrodes 17b₂ and 17b₂ arranged to sandwich the charged particle beam, and a potential difference is applied between the two electrodes 17b₂ and 17b₂ to generate an electric field, which can deflect the charged particle beam 13. The charged particle beam 13 deflected by the blanker 17b is blocked by the stopper 19 and does not reach the surface of the substrate 22, as described above.

The control unit 30 includes, for example, lens control circuits 31 and 32, drawing data conversion circuit 33, blanking control circuit 34, deflection signal generation circuit 35, deflector control circuit 36, light detection control circuit 37, stage control circuit 38, and controller 39. The lens control circuits 31 and 32 control the respective lenses 14, 16, and 21. The drawing data conversion circuit 33 converts design data supplied from the controller 39 into drawing data for blanking control of each charged particle beam. The blanking control circuit 34 controls the blanking deflector 17 based on the drawing data supplied by the drawing data conversion circuit 33. The deflection signal generation circuit 35 generates a deflection signal from the design data supplied from the controller 39, and supplies the deflection signal to the deflector control circuit 36 via a deflection amplifier (not shown). The deflector control circuit 36 controls the deflector 20 based on the deflection signal. The light detection control circuit 37 controls light detection by a light detector 28 (to be described later). The stage control circuit 38 controls movement of the substrate stage 23. Also, the controller 39 supplies design data to the drawing data conversion circuit 33 and deflection signal generation circuit 35, and controls the overall drawing operation.

In recent years, in the drawing apparatus, a demand for improving the throughput has arisen, so the number of charged particle beams is dramatically increasing to meet this demand. Therefore, data for individually controlling a plurality of charged particle beams is enormous, and must be transmitted to the drawing unit 10 at high speed via a plurality of transmission lines. For example, the charged particle beam 13 emitted by the charged particle gun 11 is divided into several ten thousand to several hundred thousand charged particle beams by the aperture array 15, and each charged particle beam undergoes blanking control by the blanking deflector 17. When such an enormous number of charged particle beams are controlled by the blanking deflector 17, drawing data which has a very large size and is generated by the drawing data conversion circuit 33 must be transmitted to the blanking deflector 17 at high speed via the blanking control circuit 34. As a transmission line used to transmit drawing data with a very large size at high speed, an optical fiber which is less subject to electromagnetic induction noise and capable of long-distance data transmission. A method of transmitting drawing data by an optical fiber from the blanking control circuit 34 to the blanking deflector 17 in the drawing apparatus 100 of the first embodiment will be described herein.

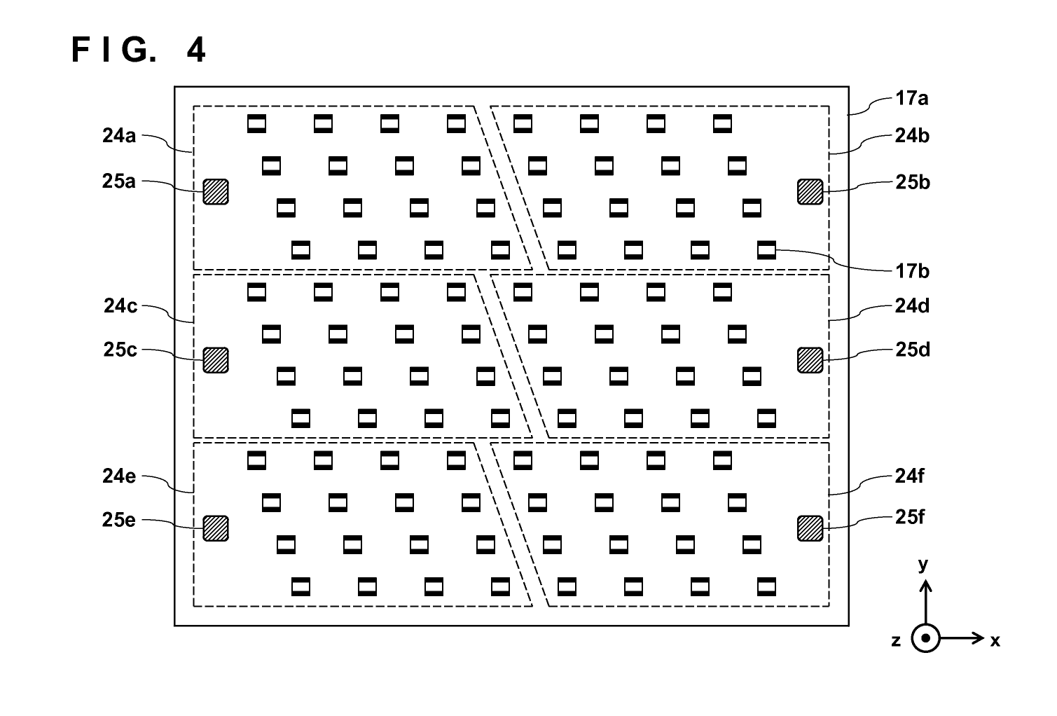

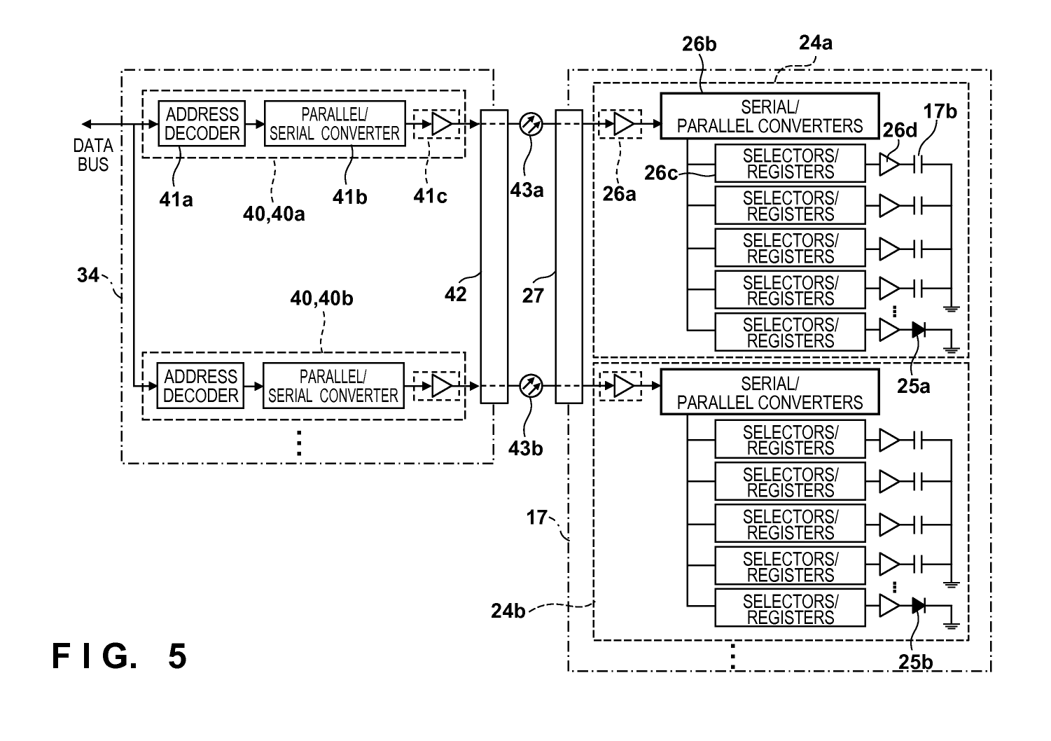

A method of transmitting drawing data in the drawing apparatus 100 of the first embodiment will be described with reference to FIGS. 4 and 5. FIG. 4 is a view showing the arrangement of a plurality of blankers 17b in the blanker array 17a of the first embodiment. A plurality of blankers 17b are arranged in correspondence with the arrangement of charged particle beams in the blanker array 17a of the first embodiment, and a plurality of signals (control signals) which control a potential difference applied to the two electrodes of each blanker 17b are transmitted via a large number of optical fibers (transmission lines). The blanker array 17a includes a plurality of groups 24 each including a plurality of blankers 17b. One optical fiber is connected to each group 24, and the plurality of blankers 17b in the each group 24 are driven based on a signal supplied by the corresponding optical fiber. That is, a plurality of blankers 17b included in one group are controlled by a signal transmitted via one optical fiber. For example, the plurality of blankers 17b in the blanker array 17a of the first embodiment are divided into six groups 24a to 24f, and each group includes 4×4 blankers 17b, as shown in FIG. 4. Optical fibers equal in number to groups are connected to the blanker array 17a, and a signal is transmitted to each group via an optical fiber corresponding to this group.

FIG. 5 is a block diagram showing transmission of signals from the blanking control circuit 34 to the blanking deflector 17. Transmission of signals to the groups 24a and 24b will be described with reference to FIG. 5, and transmission of signals to the groups 24c to 24f is the same as transmission of signals to the groups 24a and 24b, so a description thereof will not be given. The blanking control circuit 34 includes control circuits 40 equal in number to groups in the blanker array 17a, and drawing data generated by the drawing data conversion circuit 33 is sent to each control circuit 40 via a data bus. The control circuit 40 includes, for example, an address decoder 41a, parallel/serial converter 41b, and optical transceiver 41c. The address decoder 41a extracts data to be transmitted to each group from drawing data supplied by the drawing data conversion circuit 33, based on address information provided to each address decoder 41a. The data extracted by the address decoder 41a is parallel data, and the parallel/serial converter 41b converts parallel data into serial data. The optical transceiver 41c converts, into an optical signal, the serial data converted by the parallel/serial converter 41b, and transmits the optical signal to an optical fiber 43 via an optical connector 42. Also, each group 24 of the blanking deflector 17 includes, for example, an optical transceiver 26a, a serial/parallel converter 26b, a plurality of selectors/registers 26c, and a plurality of ON/OFF controllers 26d. The optical transceiver 26a receives, via an optical connector 27, the optical signal transmitted by the optical fiber 43, and converts the received optical signal into serial data. The serial/parallel converter 26b converts the serial data into parallel data, and supplies it to each selector/register 26c. Selectors/registers 26c equal in number to blankers 17b included in the group are provided in correspondence with each blanker 17b. Each selector/register 26c selects data used in the corresponding blanker 17b from parallel data supplied by the serial/parallel converter 26b. The selector/register 26c converts the selected data into timing information for controlling whether a potential difference is to be applied to the two electrodes of the blanker 17b. This timing information is a potential difference applied to the two electrodes of the blanker 17b by the ON/OFF controller 26d, and deflection of the charged particle beams is controlled. Note that the optical connectors 42 and 27 connect a plurality of optical fibers 43 to the blanking control circuit 34 and blanking deflector 17, respectively.

In this way, the blanking control circuit 34 and blanking deflector 17 are connected to each other via a plurality of optical fibers 43 so as to supply a signal to one group in the blanker array 17a via one optical fiber 43. Therefore, if improper connection has occurred in connecting the blanking control circuit 34 and blanking deflector 17 using the plurality of optical fibers 43, data is transmitted to a group different from that to be controlled. Also, if disconnection or connection failure has occurred in one optical fiber 43, an accurate signal cannot be transmitted in the group corresponding to this optical fiber 43. That is, if a problem associated with the connection state of the optical fiber 43 is present, it becomes impossible to accurately deflect the charged particle beams, and, in turn, to perform correct drawing in the drawing apparatus. As for the problem associated with the connection state of the optical fiber 43, it may become difficult to find a portion having the problem when a large number of optical fibers 43 are used. In the conventional drawing apparatus, the connection state of the optical fiber 43 is confirmed using a charged particle beam, but in this case, it is necessary to evacuate a space through which the charged particle beam passes, thus taking a long time to confirm the connection state of the optical fiber 43. To solve this problem, the drawing apparatus 100 in the first embodiment includes light-emitting elements 25 which emit light beams by a signal supplied to each group of the blanker array 17a via the optical fiber 43, and an optical fiber 43 having a problem associated with the connection state can be specified by the light emitted by the light-emitting element 25.

An LED (Light Emitting Diode), for example, is used as the light-emitting element 25, and light-emitting elements 25a to 25f are arranged near the plurality of blankers 17b in each of the groups 24a to 24f, as shown in FIG. 4. Also, the light-emitting element 25 emits light by a signal supplied from the blanking control circuit 34 to each group, as shown in FIG. 5. That is, as in the blanker 17b, the light-emitting element 25 is also supplied with parallel data from the serial/parallel converter 26b, so ON/OFF control of the light-emitting element 25 can be done via the selector/register 26c and ON/OFF controller 26d. For example, the light-emitting element 25a is arranged at a position corresponding to the group 24a on the blanker array 17a, as shown in FIG. 4, and its light emission is controlled by a signal for controlling the plurality of blankers 17b in the group 24a, as shown in FIG. 5.

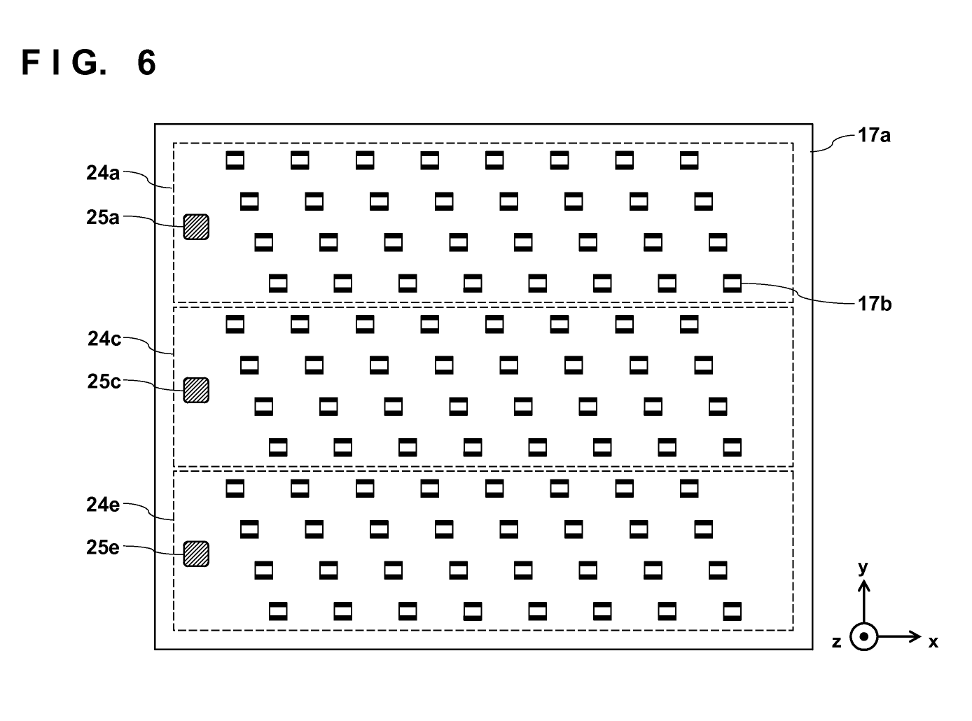

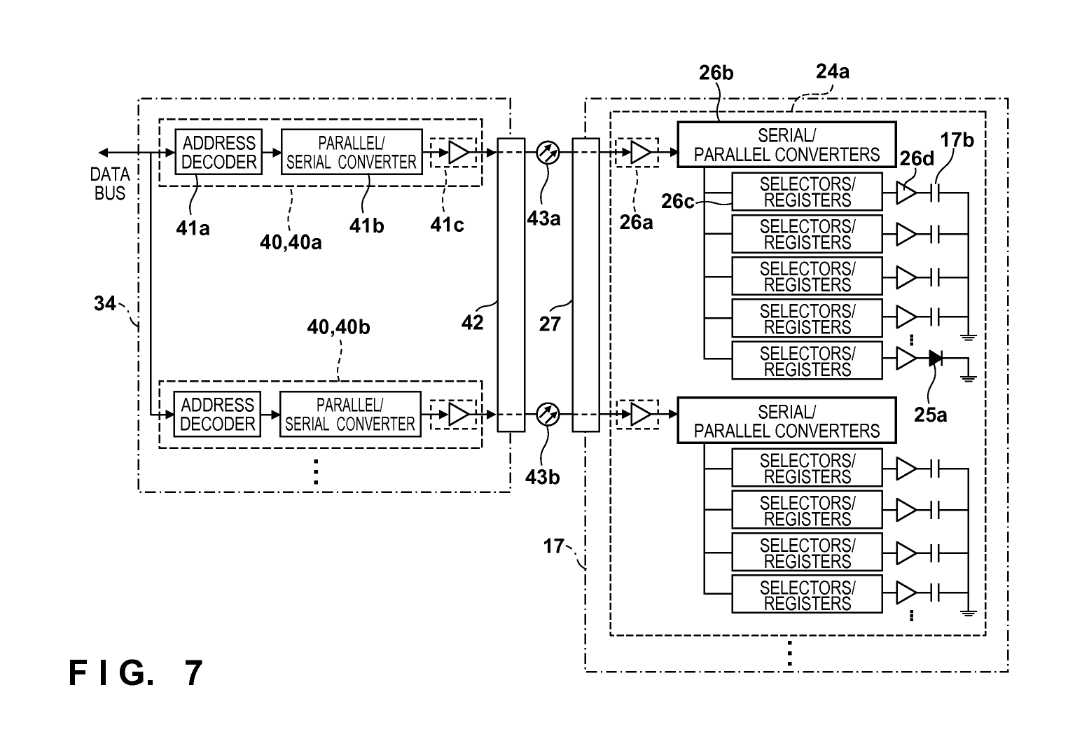

Although the plurality of blankers 17b are grouped for each optical fiber 43 which supplies a signal to them in the first embodiment, they may be grouped for each optical connector 27. When, for example, two optical fibers 43 are connected to the blanking deflector 17 by the optical connector 27, the plurality of blankers 17b in the blanker array 17a are divided into the groups 24a, 24c, and 24e, as shown in FIG. 6. The light-emitting elements 25a, 25c, and 25e are arranged in the groups 24a, 24c, and 24e, respectively, in a one-to-one correspondence. In this case, FIG. 7 is a block diagram showing transmission of signals from the blanking control circuit 34 to the blanking deflector 17, and one group (for example, the group 24a) includes two optical transceivers 26a and two serial/parallel converters 26b. On the other hand, the light-emitting element 25a is controlled by a signal transmitted via one optical fiber 43a of the two optical fibers 43. With such a configuration, the connection state of the optical connector 27 can be confirmed, and the connection state of a set of a plurality of optical fibers 43 can be confirmed.

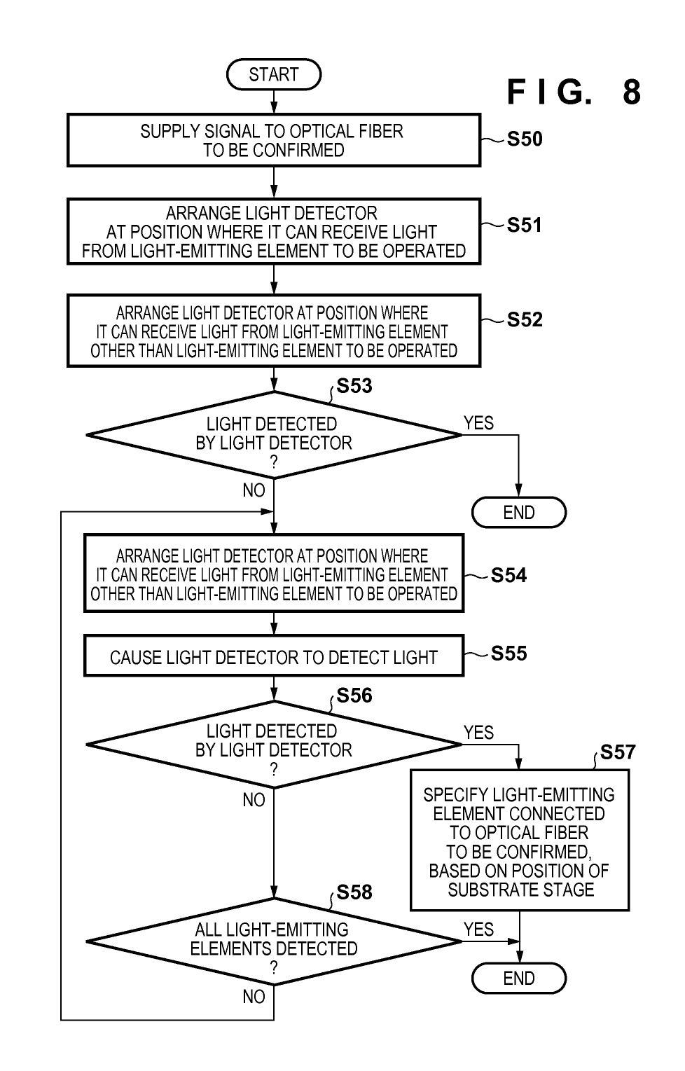

An example of a method of confirming, using the light-emitting element 25 in the drawing apparatus 100 of the first embodiment, whether a problem associated with the connection state of the optical fiber 43 is present will be described with reference to FIG. 8. FIG. 8 is a flowchart showing a method of confirming the connection state of one optical fiber 43 of a plurality of optical fibers using the light-emitting element 25. In the drawing apparatus 100 of the first embodiment, as shown in FIG. 1, the blanking deflector 17 (blanker array 17a) is provided with a plurality of light-emitting elements 25, and a light detector 28 which detects light emission of the light-emitting element 25 is provided on the substrate stage 23. At this time, the drawing apparatus 100 is configured so as to limit the light directionality of the light-emitting element 25, that is, so as not to receive light from a light-emitting element other than a light-emitting element 25 that emits light to be received by the light detector 28. Light from the light-emitting element 25 emitting light reaches the light detector 28 through a lightguide hole 19a formed in the stopper 19. The light detector 28 is set at the position where it can receive light from each light-emitting element 25 as the substrate stage 23 moves, and can detect light from this light-emitting element 25. A photodiode, for example, is used as the light detector 28, and converts detected light into an electrical signal and supplies the converted electrical signal to the light detection control circuit 37 of the control unit 30.

In step S50, the control unit 30 controls the blanking control circuit 34 to supply a signal to an optical fiber (to be referred to as “an optical fiber to be confirmed” hereinafter), the connection state of which is to be confirmed, of the plurality of optical fibers 43. In step S51, the control unit 30 controls the stage control circuit 38 to move the substrate stage 23 so as to set the light detector 28 at the position where it can receive light from a light-emitting element 25 that is to emit light by a signal supplied through the optical fiber 43 to be confirmed. In step S52, the control unit 30 controls the light detection control circuit 37 to detect light on the light detector 28. In step S53, the control unit 30 executes determination as to whether light is detected by the light detector 28. If light is detected by the light detector 28, this means that a problem associated with the connection state between the optical fiber to be confirmed and the light-emitting element to be connected is not present, so the confirmation of the connection state ends. On the other hand, if no light is detected by the light detector 28, this means that disconnection or improper connection has occurred in the optical fiber to be confirmed, so the process advances to step S54. In step S54, the control unit 30 controls the stage control circuit 38 to move the substrate stage 23 so as to set the light detector 28 at the position where it can receive light from a light-emitting element 25 other than that which is to emit light. In step S55, the control unit 30 controls the light detection control circuit 37 to detect light on the light detector 28. In step S56, the control unit 30 executes determination as to whether light is detected by the light detector 28. If light is detected by the light detector 28, the process advances to step S57; otherwise, the process advances to step S58. In step S57, the control unit 30 specifies a light-emitting element 25, connected to the optical fiber to be confirmed, based on the position of the substrate stage 23, and the confirmation of the connection state ends. In step S58, the control unit 30 executes determination as to whether light emission is detected by the light detector 28 at a position where it can receive light beams from all light-emitting elements 25. If light emission is not detected at a position where it can receive light beams from all light-emitting elements 25, the process returns to step S54, in which the control unit 30 sets the light detector 28 at a position where it can receive light from a light-emitting element 25, light from which is not detected by the light detector 28. On the other hand, if light emission is detected for all light-emitting elements 25, the confirmation of the connection state ends. If no light is detected at a position where light beams from all light-emitting elements 25 can be received, the optical fiber 43 to be confirmed may be suffering from disconnection. This sequence is performed for all optical fibers.

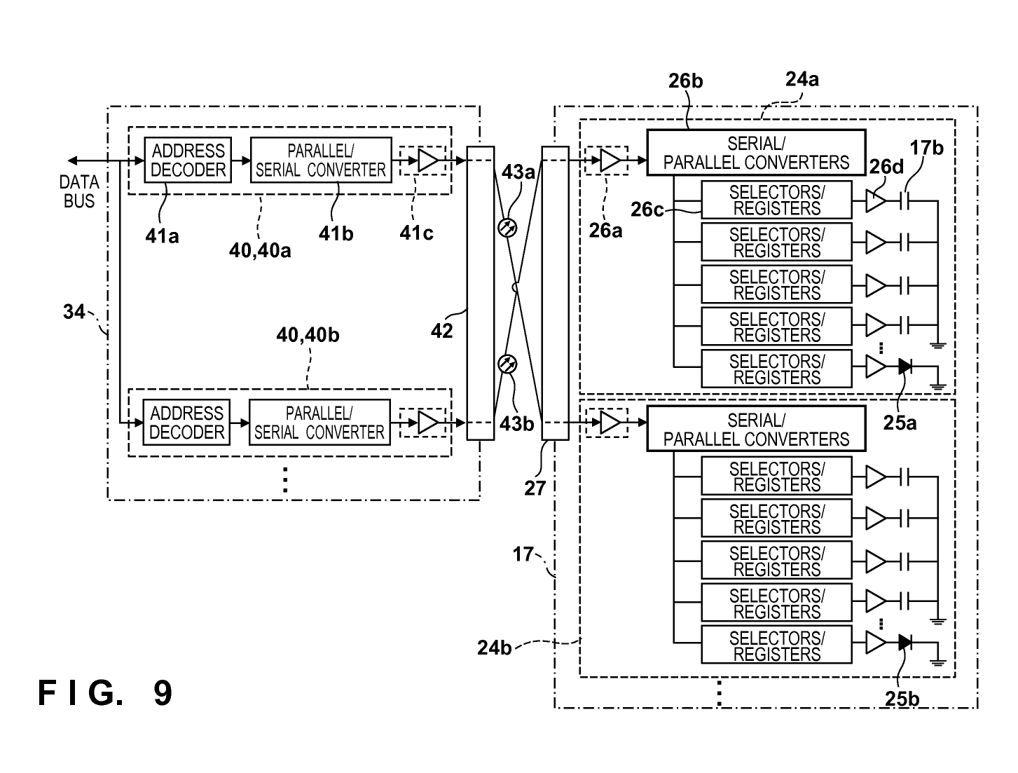

By providing the light-emitting elements 25 and light detector 28 in this way, each optical fiber 43 can be associated with a group including a light-emitting element 25 which emits light by a signal supplied by this optical fiber 43. For example, referring to FIG. 5, when the blanking control circuit 34 supplies a signal to the optical fiber 43a, if a light-emitting element that emits light detected by the light detector 28 is the light-emitting element 25a, this means that the optical fiber 43a is connected correctly. On the other hand, if the light-emitting element being emitting light is that (for example, the light-emitting element 25b) other than the light-emitting element 25a, this means that the optical fiber 43a suffers from improper connection. In this case, the control unit 30 distributes again a signal to be transmitted to each optical fiber 43, based on the association between each optical fiber 43 and the group 24 supplied with a signal by this optical fiber 43. For example, as shown in FIG. 9, assume that a control circuit 40a of the blanking control circuit 34 is connected to the group 24b of the blanking deflector 17 via the optical fiber 43a, and a control circuit 40b is connected to the group 24a via an optical fiber 43b to intersect with each other. In this case, the controller 39 controls the blanking control circuit 34 to supply a signal, to be supplied to the group 24b, from the control circuit 40a to the optical fiber 43a. Similarly, the controller 39 controls the blanking control circuit 34 to supply a signal, to be supplied to the group 24a, from the control circuit 40b to the optical fiber 43b.

As described above, in the drawing apparatus 100 of the first embodiment, the light-emitting elements 25 are provided to each group 24 in the blanker array 17a of the blanking deflector 17. Also, the light detector 28 is provided on the substrate stage 23 to detect light beams emitted by the light-emitting elements 25 of each group 24. Providing the light-emitting elements 25 and light detector 28 in this way makes it easy to confirm the connection state of the optical fiber 43 between the blanking control circuit 34 and the blanking deflector 17, thus considerably shortening the time to confirm this connection state. Although light emission of each light-emitting element 25 is confirmed by the light detector 28 set on the substrate stage 23 in the first embodiment, a mirror may be set on the substrate stage 23 to allow a human to directly confirm it. In this case, a viewport for confirming light emission of each light-emitting element 25 through a mirror is desirably set on the side wall of the drawing unit 10. Also, although the light-emitting elements 25 and light detector 28 are used in the drawing apparatus 100 of the first embodiment, another configuration in which, for example, an element that generates a radio wave with high directionality, and a detector that detects the radio wave are used may be employed.

### Second Embodiment

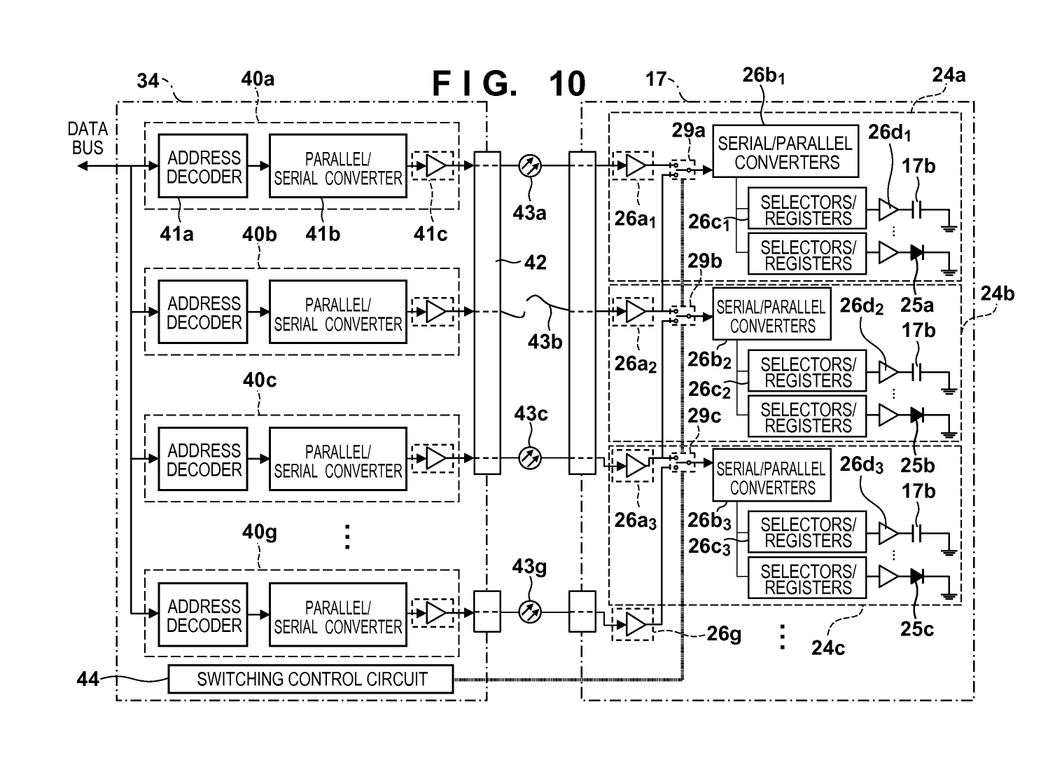

A drawing apparatus in the second embodiment of the present invention will be described. In the drawing apparatus of the second embodiment, even if a disconnected optical fiber is present, a signal can be correctly supplied to each group in a blanker array 17a. FIG. 10 is a block diagram showing transmission of signals from a blanking control circuit 34 to a blanking deflector 17 in the drawing apparatus of the second embodiment. Referring to FIG. 10, transmission of signals to groups 24a to 24c in FIG. 4 will be described, and a description of transmission of signals to groups 24d to 24f will not be given.

In the drawing apparatus in the second embodiment, unlike the drawing apparatus 100 in the first embodiment, a plurality of switching units 29 are included in the blanking deflector 17, and a switching control circuit 44 is included in the blanking control circuit 34. The switching unit 29 is arranged between an optical transceiver 26a and a serial/parallel converter 26b in each group of the blanker array 17a, and is controlled by the switching control circuit 44 so as to switch the connection between the optical transceiver 26a and the serial/parallel converter 26b. For example, a serial/parallel converter 26b₁ is wired so as to be connected to an optical transceiver 26a₁ or 26a₂, and its connection can be switched by a switching unit 29a. Also, control circuits 40 larger in number than groups in the blanker array 17a are included in the blanking control circuit 34, and are connected to an optical transceiver 26g in the blanking deflector 17 via an optical fiber and an optical connector. For example, not only control circuits 40a to 40c corresponding to the groups 24a to 24c, respectively, in the blanking deflector 17, but also a control circuit 40g is included in the blanking control circuit 34 shown in FIG. 10. An optical signal generated by the optical transceiver of the control circuit 40g is supplied to the optical transceiver 26g of the blanking deflector 17 via the optical connector and optical fiber. A method of correctly supplying a signal to each of the groups 24a to 24c when the optical fiber 43b is disconnected will be described herein.

First, the optical transceiver 26a₁ and serial/parallel converter 26b₁ are connected to each other by the switching unit 29a, the optical transceiver 26a₂ and a serial/parallel converter 26b₂ are connected to each other by a switching unit 29b, and an optical transceiver 26a₃ and serial/parallel converter 26b₃ are connected to each other by a switching unit 29c. In a state in which the optical transceivers 26a are connected to the corresponding serial/parallel converters 26b, the groups corresponding to optical fibers 43a to 43c are confirmed based on the flowchart shown in FIG. 8. Since the light-emitting element 25 for emitting light upon supplying a signal to the optical fiber 43b is not present, the disconnection of the optical fiber 43b is confirmed. Since the connections of the groups corresponding to the optical fibers 43a and 43c can be confirmed based on the flowchart in FIG. 8, the disconnection of only the group corresponding to the optical fiber 43b can be confirmed.

The optical fiber 43b is disconnected. For this reason, the optical transceiver 26a₃ is connected to the serial/parallel converter 26b₂ by the switching unit 29b, and the optical transceiver 26g is connected to the serial/parallel converter 26b₃ by the switching unit 29c. In this state, the groups corresponding to the optical fibers 43c and 43g can be confirmed based on the flowchart shown in FIG. 8. This makes it possible to associate the optical fibers 43 with the groups 24. Based on this association, signals are supplied to the respective optical fibers 43 from the control circuits 40 of the blanking control circuit 34. For example, the controller 39 controls the blanking control circuit 34 so that the signal supplied to the group 24b is supplied from the control circuit 40c to the optical fiber 43c. Similarly, the controller 39 controls the blanking control circuit 34 so that the signal supplied to the group 24c is supplied from the control circuit 40g to the optical fiber 43g.

As described above, in the drawing apparatus of the second embodiment, the blanking deflector 17 includes the switching unit 29 for switching the connection between the optical transceiver 26a and the serial/parallel converter 26b. The blanking control circuit 34 includes control circuits 40 larger in number than the number of groups in the blanker array 17a. When the blanking deflector 17 and the blanking control circuit 34 are arranged as described above, even if the optical fiber 43 is disconnected, a correct signal can be supplied to each group 24 without replacement or reconnection of the optical fiber.

### Third Embodiment

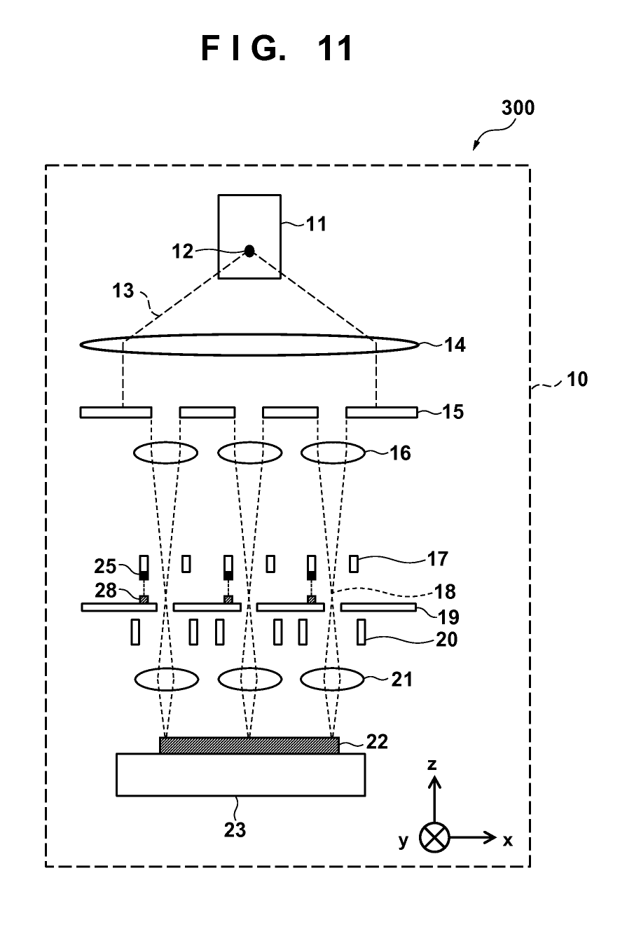

A drawing apparatus 300 according to the third embodiment of the present invention will be described with reference to FIG. 11. The drawing apparatus 300 of the third embodiment is different from the drawing apparatus 100 of the first embodiment in the position where a light detector 28 is arranged, and the number of light detectors 28. In the drawing apparatus 300 of the third embodiment, the plurality of light detectors 28 are arranged on a stopper 19 so as to correspond to light-emitting elements 25 in different groups 24. As described above, since the plurality of light detectors 28 are arranged on the stopper 19, the emitting operations of the plurality of light-emitting elements 25 can be simultaneously detected. For this reason, the time required to confirm the connection state of the optical fiber 43 between a blanking control circuit 34 and a blanking deflector 17 can be greatly shortened. The plurality of light detectors 28 may be arranged in the Z-direction with respect to the light-emitting elements 25. For example, the plurality of light detectors 28 may be arranged on an aperture array 15. In this case, the light-emitting element 25 emits light in the z direction.

### Fourth Embodiment

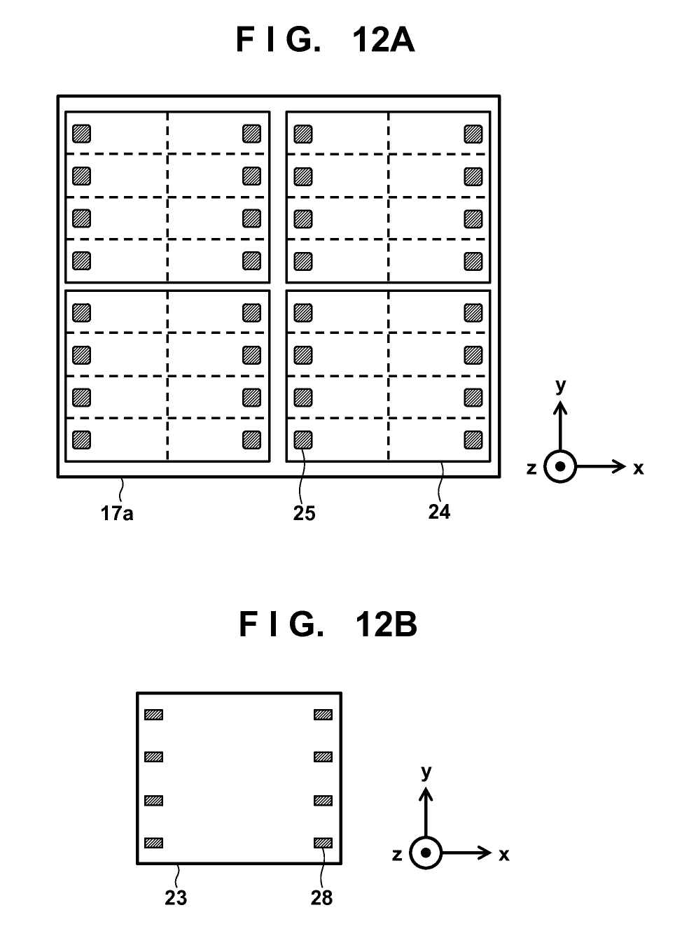

A drawing apparatus 400 of the fourth embodiment of the present invention will be described with reference to FIGS. 12A and 12B. The drawing apparatus 400 of the fourth embodiment is different from the drawing apparatus 100 of the first embodiment in that a plurality of light detectors 28 are arranged on a substrate stage 23. For example, as shown in FIG. 12A, when a plurality of blankers 17b in a blanker array 17a are divided into 32 groups, the blanker array 17a includes 32 light-emitting elements 25. In this case, if the number of light detectors 28 arranged on the substrate stage 23 is one, it takes a long time to detect all the light-emitting elements 25. For this reason, as shown in FIG. 12B, the eight light detectors 28 are arranged at positions on the substrate stage 23 which correspond to the eight light-emitting elements 25, thereby simultaneously detecting the emission operations of the plurality of light-emitting elements 25 and greatly shortening the time to confirm the connecting states of optical fibers 43.

<Embodiment of Method of Manufacturing Article>

A method of manufacturing an article according to an embodiment of the present invention is suitable for manufacturing various articles including a microdevice such as a semiconductor device and an element having a microstructure. The method of manufacturing an article according to this embodiment includes a step of forming a latent image pattern on a photosensitive agent, applied onto a substrate, using the above-mentioned drawing apparatus (a step of performing drawing), and a step of developing the substrate having the latent image pattern formed on it in the forming step. This manufacturing method also includes subsequent known steps (for example, oxidation, film formation, vapor deposition, doping, planarization, etching, resist removal, dicing, bonding, and packaging). The method of manufacturing a device according to this embodiment is more advantageous in terms of at least one of the performance, quality, productivity, and manufacturing cost of a device than the conventional method.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-183594 filed on Aug. 22, 2012, which is hereby incorporated by reference herein in its entirety.

What is claimed is:

1. A drawing apparatus for performing drawing on a substrate with a plurality of charged particle beams, comprising:
a blanker array including a plurality of groups each including one light-emitting element and at least one blanker; and
a plurality of transmission lines configured to transmit control signals to the plurality of groups, respectively,
wherein each light-emitting element emits light when a signal is transmitted via a transmission line connected to a group including the light-emitting element out of the plurality of transmission lines.

2. The apparatus according to claim 1, further comprising:
a movable substrate stage including a light detector and configured to hold the substrate; and
a controller configured to specify a connecting state between one of the plurality of groups and one of the plurality of transmission lines, based on a position of the substrate stage when the light detector detects light.

3. The apparatus according to claim 2, wherein the controller specifies the connecting state by supplying a signal to each transmission line.

4. The apparatus according to claim 3, wherein the controller supplies a signal to each transmission line so that a signal is supplied to each group to which the signal should be supplied, based on the connecting state.

5. The apparatus according to claim 1, further comprising:
a plurality of light detectors arranged at positions respectively corresponding to the light-emitting elements; and
a controller configured to specify a connecting state between one of the plurality of groups and one of the plurality of transmission lines, based on a position of a light detector which has detected light out of the plurality of light detectors.

6. The apparatus according to claim 5, wherein the controller specifies the connecting state by supplying a signal to each transmission line.

7. The apparatus according to claim 6, wherein the controller supplies a signal to each transmission line so that a signal is supplied to each group to which the signal should be supplied, based on the connecting state.

8. The apparatus according to claim 2, further comprising a switching unit configured to switch a connecting state between the plurality of transmission lines and the plurality of groups,
wherein the controller controls the switching unit so that when a signal is not supplied to one group via one transmission line connected to the one group, the signal is supplied to the one group via another transmission line.

9. A method of manufacturing an article, the method comprising:
performing drawing on a substrate using a drawing apparatus;
developing the substrate on which the drawing has been performed; and
processing the developed substrate to manufacture the article,
wherein the drawing apparatus, the apparatus performing drawing on substrates with a plural of charged particle beams, the apparatus comprising:
a blanker array including a plurality of groups each including one light-emitting element and at least one blanker; and
a plurality of transmission lines configured to transmit control signals to the plurality of groups, respectively,
wherein each light-emitting element emits light when a signal is transmitted via a transmission line connected to a group including the light-emitting element out of the plurality of transmission lines.
